(19) United States
(12) Patent Application Publication
(10) Pub. No.: US 2012/0068339 A1
(43) Pub. Date: Mar. 22, 2012

(54) VLSI Package for High Performance Integrated Circuit

(75) Inventors: Michael J. Miller, Saratoga, CA (US); Mark W. Baumann, Campbell, CA (US)

(73) Assignee: MOSYS, INC., Santa Clara, CA (US)

(21) Appl. No.: 12/887,298

(22) Filed: Sep. 21, 2010

(51) Int. Cl. H01L 23/498; H01L 21/60

(52) U.S. Cl. 257/738; 438/613; 257/E23.069; 257/E21.508

(57) ABSTRACT

A packaged integrated circuit is presented for placement on a printed circuit board (PCB) layer providing power lines and data access channels. The packaged integrated circuit includes; a package substrate having data channels and power lines; a circuit substrate having functional components, wherein (a) the power lines and the data channels in the package substrate are coupled to the functional components of the substrate by conducting bumps, (b) the conducting balls coupling the data access channels in the PCB to the data channels in the package substrate are located along the edges of the package substrate; and (c) the conducting balls coupling the power lines in the PCB and the power lines in the package substrate are located in an interior portion of the package substrate. Also, an integrated circuit may further include a circuit substrate having active components, including a SerDes circuit at a center portion of the substrate.

### RELATED APPLICATIONS

This application is related to commonly owned U.S. patent application Ser. No. 12/846,763 entitled “Semiconductor Chip Layout,” by Michael J. Miller and Mark W. Baumann, filed Jul. 29, 2010, which is hereby incorporated by reference in its entirety.

1. Field of the Invention

The present invention relates to integrated circuit design, including memory circuit design.

2. Background

Current memory circuits that make use of double data rate (DDR) and quadruple data rate (QDR) access schemes have separate address, write data, read data and status pins. These access schemes require high frequency data transmission links that provide low bit error rate (BER), high bandwidth and low on-chip latency. Bandwidth is the amount of information exchanged during read and write operations. Latency is the time lapsed between an event in an input signal and a corresponding event in an output signal that results from the event in the input signal. For example, in a memory circuit latency is the time lapsed between the receipt of a ‘Read’ command at an input pin of the memory circuit and the transmission of the corresponding read data to the output pins of the memory circuit.

Because of the complexity of synchronizing multiple data bits in a parallel data link and the limitation of singled ended electrical schemes like high-speed transceiver logic (HSTL) and stub series terminated logic (SSTL), differential serial data transmission links are becoming more common for chip to chip communications. In a device that has a serial transmission link, a transmitted data packet may have a long latency, especially when error checking is used to ensure data integrity, as data integrity cannot be established until the entire packet has been processed. Often serial links are used in packet processing circuits in pairs of ‘transmit’ (Tx) and ‘receive’ (Rx) data channels because traffic is balanced between packets received and packets transmitted. This configuration often results in interference in the Rx signal due to cross-talk from the higher power in the Tx data channels. As serial links are considered for addressable devices with smaller data quanta like memory or arrays of computational elements, the expectation of balance information in and out no longer can be held true. An Rx channel normally requires a greater bandwidth to communicate a command, data to be written, and address bits in a given frame or data packet. On the other hand, a Tx channel typically needs bandwidth only to include data that are read. Thus, pairing of Tx/Rx channels may result in insufficient bandwidth for the Rx channel, or an inefficient utilization of bandwidth for a Tx channel.

In a device that has a serial transmission link one or more serializer-deserializer (SerDes) circuits convert data packets between serial and parallel formats. It is common practice to place the SerDes circuits and other associated logic components along the periphery of the silicon chip. Such architecture results in a wide spread in latencies in the silicon, depending on the distance between the SerDes and the specific functional block that is the source or the destination of the data. Thus, worst case timing latency is determined by the longest path set by the I/O which is the furthest away from any one of the memory location. A typical layout of I/O at the periphery would result in the worst case path from one corner of the die to the opposite corner. The resulting distance that an input signal must traverse could be the width plus the height of the die.

Error rates are expected to increase for high speed data links. Many circuits have an error detection circuit, such as a cyclic redundancy check (CRC) circuit to perform error checking on data packets. Error checking must be performed across the entire data packet, which may be striped across multiple data lines to reduce latency. However, such an approach requires that multiple data lines converge into the error detection circuit to allow error checking, thus adding to the length of the traces that signals must traverse for an operation. Likewise there can be error detection on data coming from the memory before it is put in the data packets. This requires Boolean arithmetic to be performed on the entire word that is then compared against check bits associated with the data word that were created at the time the data word was stored. This is often referred to as Error Detection and Correction (EDC). Sometimes only detection is implemented because correction is optional or is handled in another part of the system. Sometimes the additional EDC information travels across the serial links in the data packet along with the data words in order to provide end to end data integrity. By checking the data word as it passes between the memory and the SerDes, system integrity is enhanced, thereby providing an additional level of checking and further fault isolation. Other coding schemes for error detection can be conceived but will have the same requirements of calculating across the entire data word or packet and comparing results against associated check bits creating routing delay and increased latency.

Moreover, heaviest packet traffic in a device typically occurs as communication among functional blocks formed in or on the silicon substrate. Data lines formed in or on the silicon substrate are impeded by significant capacitive and resistive loads to the packet traffic. In addition, communication lines in or on silicon further need to circumvent the functional blocks that create barriers to signal routing, adding to the lengths of the communication lines. As a result, on die packet traffic routed through communication lines on a silicon substrate with a significant density of functional blocks will experience increased latencies.

In an application using a SerDes circuit, placement of a power pin next to a data pin in a package substrate complicates “signal escape” to an external component. Routing signals in a printed circuit board from a signal pad at the center of the chip through a “picket fence” of power pins exposes the data signal on the signal pad to interference, cross-talk, and distortion. Thus, packages where the signal pins are placed toward the outer edges of the packet reduce the picket fence effect. To overcome the above problem, it is customary to place I/O signals at the edge of the silicon substrate. However such placement can negatively impact the overall latency of the circuit. Package pin-out configuration is a concern in integrated circuit design. What is desired is an integrated circuit and package layout that reduces data latency while easing printed circuit board layout.

### SUMMARY

A packaged integrated circuit is disclosed which is designed for placement on a printed circuit board (PCB) on which power lines and data channels are provided. The packaged integrated circuit includes a package substrate containing Rx and Tx data channels that are located on opposite sides of the package substrate; a circuit substrate containing functional circuits that are coupled to power lines and data channels on the package substrate by conducting solder bumps. The data channels on the PCB layer couple data channels in the package substrate through conducting or solder balls that are located along the periphery of the package substrate; and conducting balls in an interior portion of the package substrate couple power lines on the PCB layer to power lines in the package substrate.

Also, a packaged integrated circuit designed to be placed on a PCB is presented, the PCB having power lines and data access channels formed thereon. The packaged integrated circuit includes: a circuit substrate that includes active components and a SerDes circuit centrally located in the circuit substrate; a package substrate having transmit and receive data channels and power lines, the data channels in the package substrate being coupled through the SerDes circuit to active components on the substrate by conducting bumps; the transmit and receive data channels and power lines in the package substrate are positioned for coupling the power lines and the data access channels on the PCB layer through conducting balls, Specifically, the conducting balls that couple the data access channels in the PCB layer to the transmit and receive data channels in the package substrate are located along the periphery of the package substrate; and the conducting balls positioned for coupling the power lines in the PCB layer and the power lines in the package substrate are located in an interior portion of the package substrate.

These and other embodiments of the present invention are further described below with reference to the following figures.

### BRIEF DESCRIPTION OF THE DRAWINGS

FIG. 1 shows a packaged integrated circuit and a PCB in accordance with the present invention.

FIG. 2 shows the cross-section of a packaged integrated circuit on a printed circuit board in accordance with the present invention.

FIG. 3 shows a layout of a package substrate in an integrated circuit memory device in accordance with the present invention.

FIG. 4 shows a circuit substrate for an integrated circuit including a memory array in accordance with the present invention.

FIG. 5a is a conducting ball grid array map or bonding diagram showing the positions of conductive balls that connect package substrate 300 to underlying PCB 200, in accordance with the present invention.

FIG. 5b is a conducting bump array map or bonding diagram showing the positions of solder bumps which couple circuit substrate 400 to underlying package substrate 300 in accordance with the present invention.

FIG. 5c shows a layout of package substrate 300, including conductor traces 550-1 to 550-16 and 552-1 to 552-16, serving as Tx data lines and Rx data lines, respectively, between conductor balls at opposite edges of package substrate 300 and SerDes circuits 401 and 420 on circuit substrate 400 in accordance with the present invention.

FIG. 6 shows three different arrangements for Rx signal pairs provided on a package substrate in accordance with the present invention.

FIG. 7 shows a cross section of a semiconductor package of the present invention.

To simplify the detailed description below, the same reference numbers are used throughout the drawings to refer to the same or similar elements.

### DETAILED DESCRIPTION

In integrated circuit design, serial data communication links are used increasingly frequently. A serial communication link is less likely to suffer from channel-to-channel cross-talk and capacitive coupling, both of which may reduce the bandwidth of the data communication link. In a serial communication link of a memory device, address, control and data to be written are all received in the same ‘receive’ (Rx) channel. Also, the Read data and status bits are transmitted in a paired ‘transmit’ (Tx) channel of the serial communication link This arrangement increases the risk of bit flips along the length of the serial communication link

To provide serial data communication links, serializer-deserializer (SerDes) circuits are introduced in integrated circuits (e.g. memory arrays or arrays of computational elements). A SerDes circuit includes a serializer and a deserializer. The deserializer converts data packets received from a serial communication link into a parallel form that is used in the logic circuits, data processors, and memory arrays of the integrated circuit. The serializer converts data packets in parallel form to a serial form. Often, the serialized data packets are transmitted out of the integrated circuit to external circuitry (‘signal escape’).

A packaged integrated circuit in some embodiments of the present invention is designed to be placed on a printed-circuit board (PCB). The packaged integrated circuit includes a package substrate on which data channels and power lines are formed, and a circuit substrate in which active circuitry or components are formed. The circuit substrate may be a semiconductor die, which may be made of silicon, or a combination of silicon and germanium, or other semiconductor materials and alloys, such as gallium arsenide, or indium phosphide. The circuit substrate may include a number of functional components formed therein that may be active components for performing logic operations on data, storage components for storing data, or both. Some embodiments of the present invention may include a combination of active and storage components in the integrated circuit. In some embodiments of the present invention, the circuit substrate may be an application specific integrated circuit (ASIC) that includes a SerDes circuit, and an error detection circuit, such as a cyclic redundancy check (CRC) circuit or EDC for memory. Some embodiments may further include memory components such as arrays of memory cells (“memory array”) formed in the circuit substrate. Examples of memory arrays may include static random access memory (SRAM) arrays or dynamic random access memory (DRAM) arrays.

The present invention provides a serial communication interface for an integrated circuit (e.g., a memory integrated circuit) which addresses package level concerns. For example, using a SerDes circuit may desirably reduce the number of intervening layers in a resulting package. Also, signal latencies between input and output pins may become relevant, and a circuit architecture that provides a reduced time between input and output data may also be desirable. In particular, a high speed memory is sensitive to latency, especially in conjunction with the DDR and QDR data schemes currently in use. Latency across a memory chip may be lower than a few 100's of picoseconds, according to some embodiments of the present invention.

Further embodiments of the present invention provide a training or calibration procedure adjusting the transmission of data packets in the circuit to the actual operating conditions. Such training or calibration procedure may be carried out, for example, at power-up. During the training or calibration procedures, storage elements formed in various sectors of the circuit substrate are programmed with pre-defined patterns and read. Thus, the number of clock cycles representing the signal delays between the SerDes and the different sectors in the circuit substrate may be determined. This calibration adjusts for internal timing. Also, the number of clock cycles representing signal delays between the packaged integrated circuit and external circuits may be determined by similarly requiring the external circuits to transmit to the packaged integrated circuit one or more pre-defined bit sequences. This calibration adjusts for external timing. Internal timing and external timing calibrations are used in the SerDes circuit to send and receive data packets. An error detection circuit (such as a CRC circuit) may be periodically polled and once the error rate exceeds a tolerance limit, a recalibration procedure may be initiated.

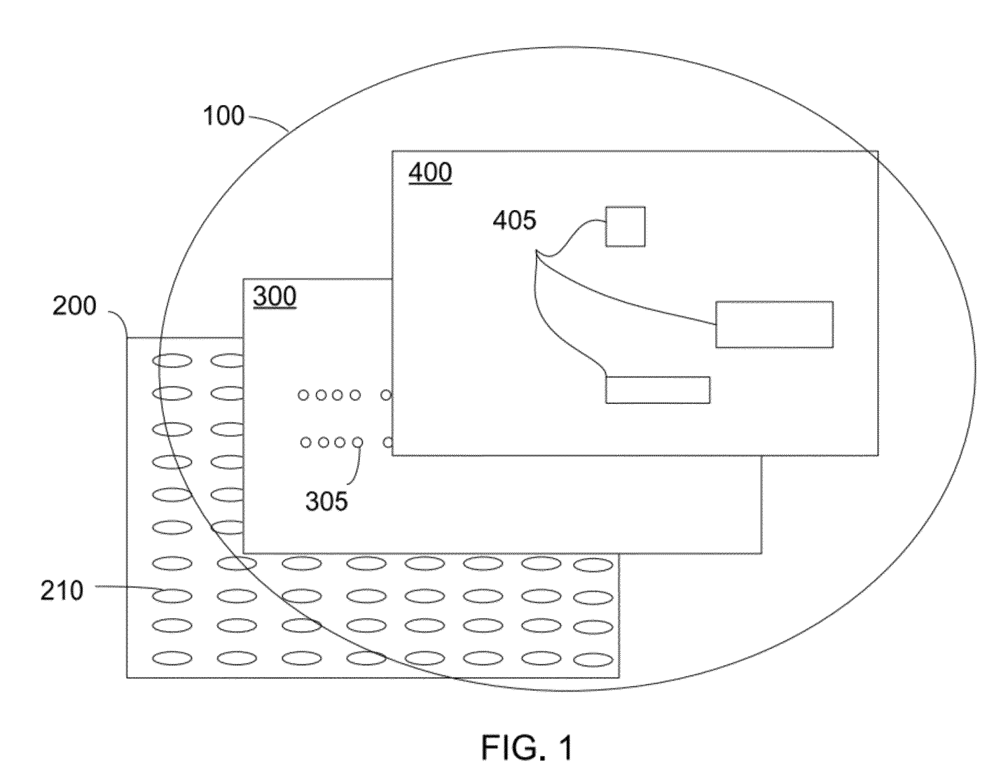

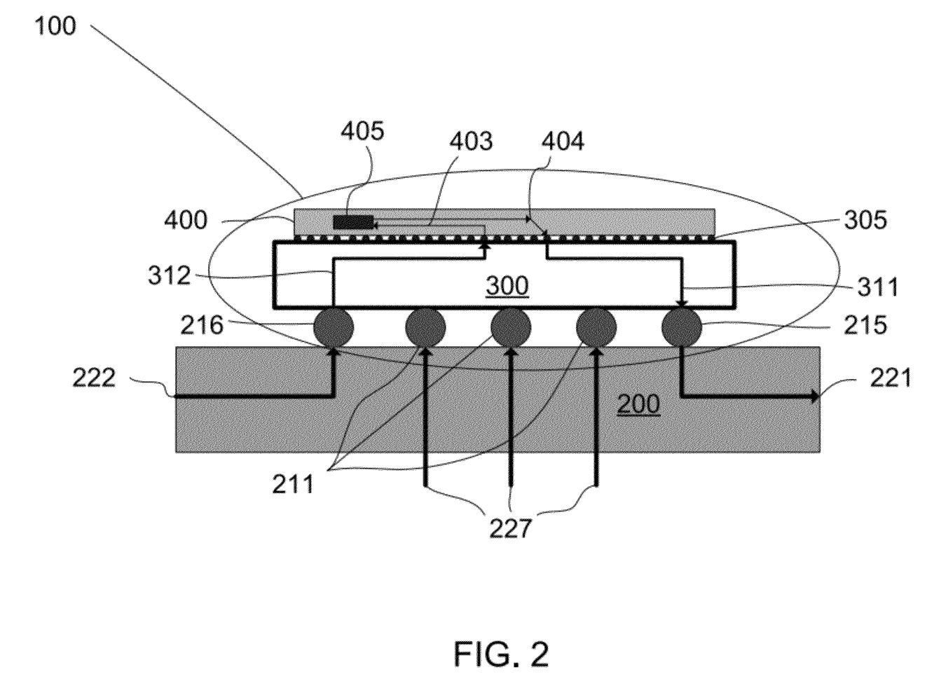

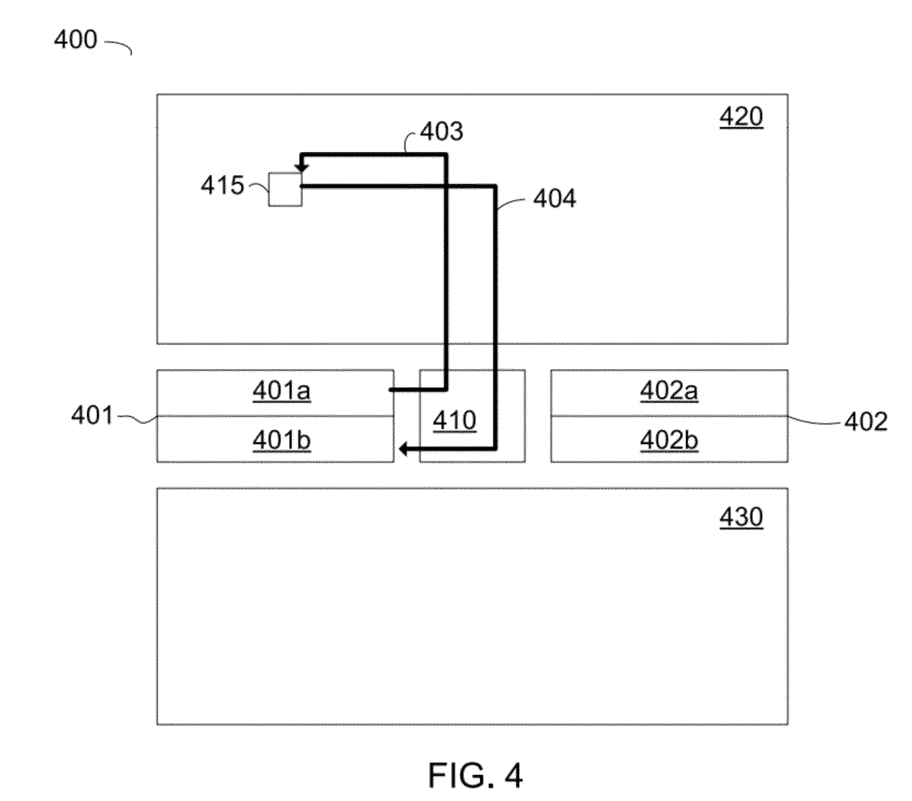

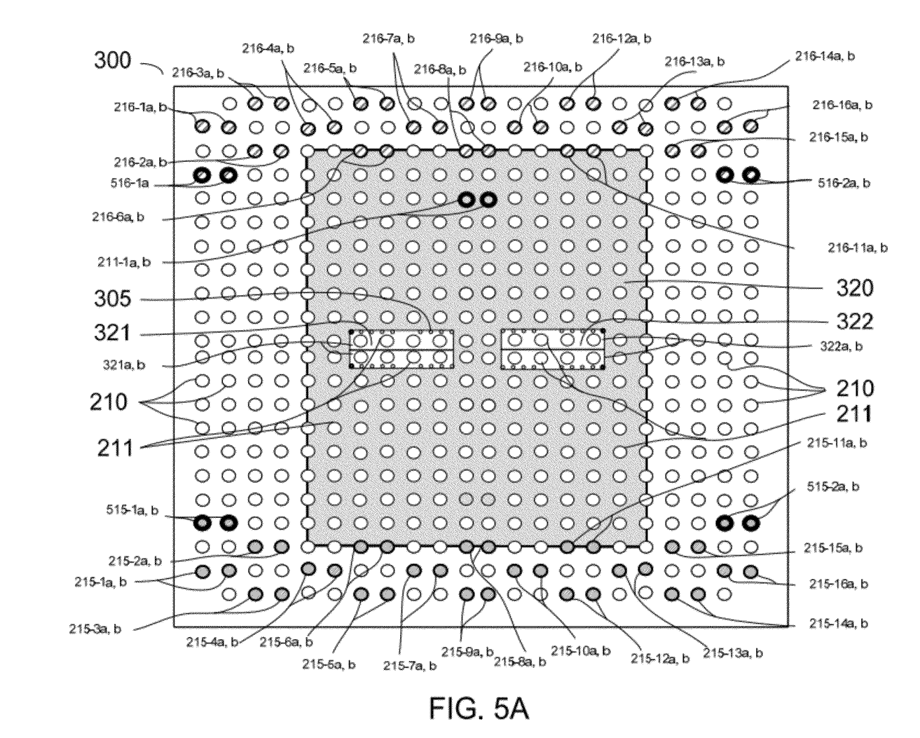

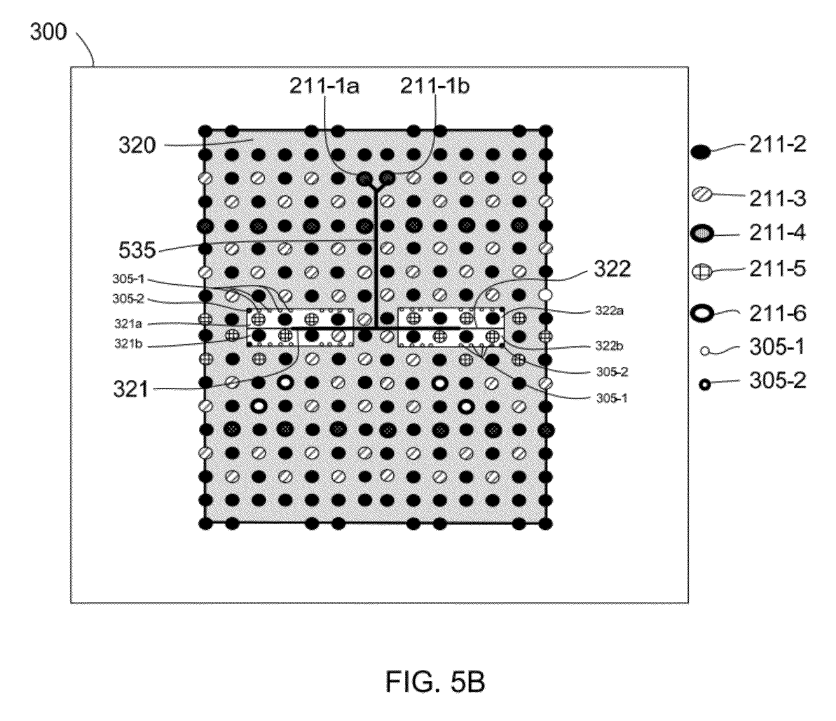

FIG. 1 shows a packaged integrated circuit 100 according to some embodiments of the present invention. Packaged integrated circuit 100 is placed on PCB 200, and includes package substrate 300, and circuit substrate 400. PCB 200 may provide power lines and data access channels (not shown in FIG. 1) for coupling packaged integrated circuit 100 with external components. The power lines and data access channels formed on PCB 200 are coupled to package substrate 300 through conducting or solder balls 210. Package substrate 300 may also include power lines and data channels (not shown in FIG. 1; but, see FIGS. 5b and 5c) that link the power lines and data channels of PCB 200 to circuit substrate 400. The power lines and the data channels in package substrate 300 are coupled to circuit substrate 400 by conducting or solder bumps 305. Conducting bumps 305 electrically connect package substrate 300 and the functional components 405 formed in circuit substrate 400 through data lines 403 and 404 (not shown in FIG. 1; but, see FIG. 2, data lines 403 and 404). Data lines 403 and 404 carry data packets and clock signals back and forth between conducting bumps 305 and functional components 405. Data carried by data lines 403 and 404 may include data packets in serial or parallel form, according to some embodiments of the present invention. Further, some embodiments of the present invention may carry data packets in serial form through a portion of data lines 403 and 404, and in parallel form through a portion of data lines 403 and 404.

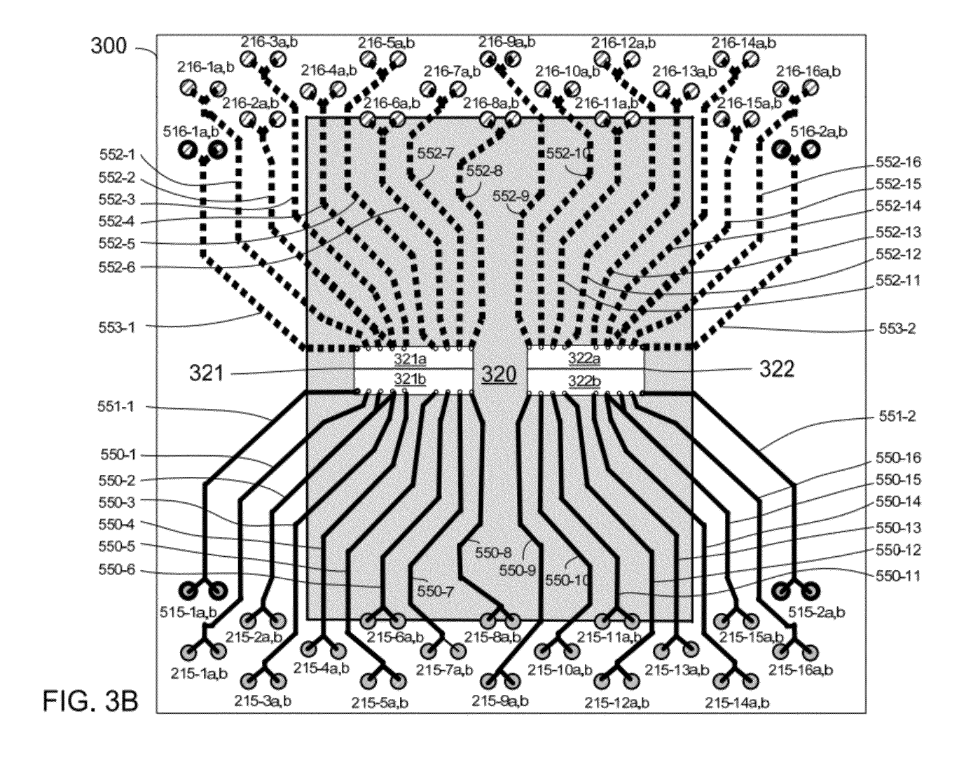

Packaged integrated circuit 100 depicted in FIG. 1 provides efficient distribution of data traffic across different circuit layers. Package substrate 300 performs part of the data transfer from a location near or at the periphery of packaged integrated circuit 100 to a central portion of circuit substrate 400. In some embodiments of the present invention, circuit substrate 400 is a semiconductor die 400 in a “flip chip” configuration that allows bonding pads on one surface of the semiconductor die to bond with corresponding conducting or solder bumps provided on package substrate 300. Package substrate 300 brings Rx data from a location near or at the periphery of the semiconductor die to a central portion of the semiconductor die 400, and the Tx data from the central portion to the periphery of the semiconductor die 400. Rx and Tx channel lines may be placed on and routed through non-overlapping portions (e.g., opposite sides) of package substrate 300. Also, crosstalk and interference between Tx and Rx channels may be avoided, as they are located by design on non-overlapping portions. Circuit substrate 400 provides signals between the central portion of the semiconductor die 400 and functional components 405 that may be located along the periphery of the integrated circuit, using data lines 403 and 404 (see, e.g., FIGS. 2 and 4). According to some embodiments of the present invention, data lines 403 and 404 carry data at a lower data rate in circuit substrate 200 than data lines in package substrate 300. The lower data rate in lines 403 and 404 relative to channel lines in package substrate 300 may be compensated by data packet transmission in parallel form through a portion or the entirety of lines 403 and 404.

FIG. 2 shows a cross section of packaged integrated circuit 100 according to some embodiments of the present invention. PCB 200 includes data channel 221 that provides the Tx data from packaged integrated circuit 100 to external components, and data channel 222 that provides the Rx data to packaged integrated circuit 100. Power lines 227 coupled to PCB 200 provide voltage and current to enable functional components 405 formed in circuit substrate 400. Power lines 227 and data channels 221 and 222 are coupled to package substrate 300 through conducting balls 210. Conducting balls 210 may include conducting balls 211, which couple power lines 227 from PCB layer 200 to package substrate 300. Conducting balls 210 may also include conducting balls 215, which couple Tx data channels 221 in PCB 200 to Tx data channels 311 in package substrate 300. Conducting balls 210 may further include conducting balls 216, which couple Rx data channels 222 in PCB 200 to Rx data channels 312 in package substrate 300.

Conducting bumps 305 couple data channels 311 and 312 from package substrate 300 to circuit substrate 400. Further, according to the embodiment depicted in FIG. 2, data lines 403 and 404 couple data channels 311 and 312 through conducting bumps 305 to functional components 405 in circuit substrate 400. Conducting bumps 305 also provide power to circuit substrate 400 to enable functional components 405. Power is provided from lines 227 coupled through conducting balls 211 and package substrate 300.

According to some embodiments of the present invention as depicted in FIG. 2, conducting balls 211 are coupled to an interior portion of package substrate 300. In contrast, conducting balls 215 and 216 are coupled to outside portions of package substrate 300. Thus, data packets being transferred through package substrate 300 have substantially reduced electromagnetic coupling to electromagnetic fields generated by power lines 227. Moreover, according to some embodiments of the present invention such as depicted in FIG. 2, Tx data channels 311 are provided on one portion of package substrate 300 (e.g., right-hand side of the cross-section). And Rx data channels 312 are provided on another portion of package substrate 300 (e.g., on the left-hand side of the cross-section). Thus, cross-coupling between Tx and Rx data packets may also be substantially reduced. Therefore, the problem of having higher power Tx data channels 311 interfering with lower power Rx data channels 312 may be avoided.

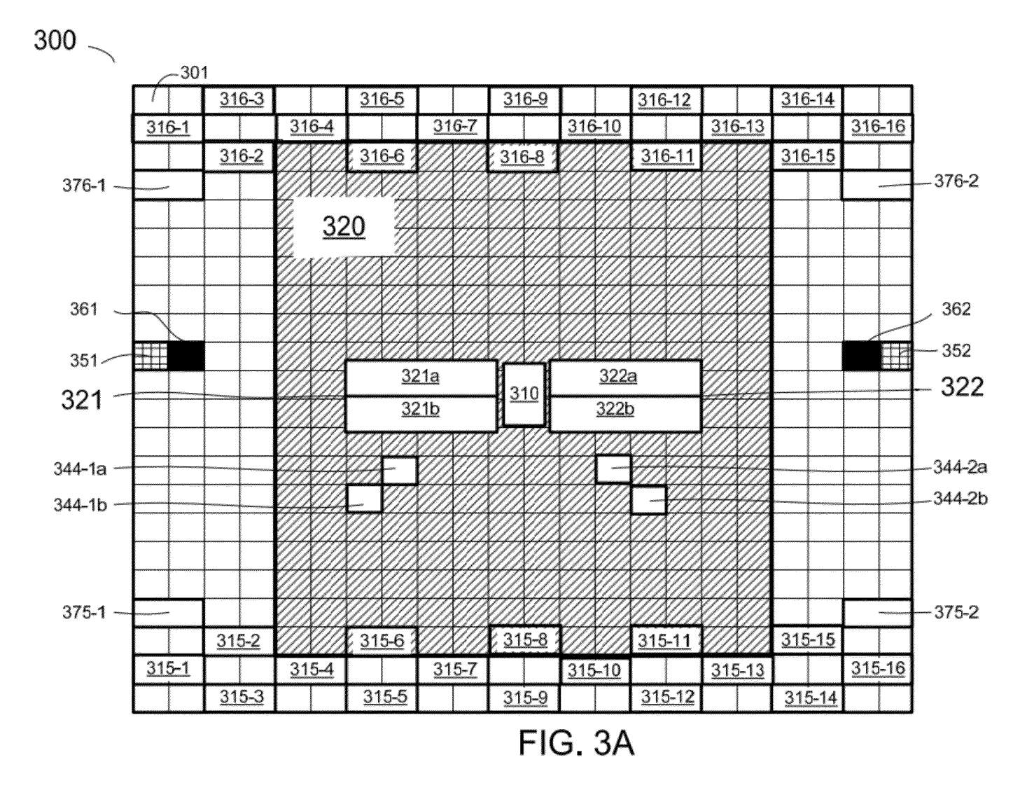

FIG. 3 shows the layout of package substrate 300 in an integrated circuit memory device according to some embodiments of the present invention. Package substrate 300 may be divided into a number of divisions 301 forming an M (vertical)×N (horizontal) matrix, where M and N are integer numbers. According to the embodiment of FIG. 3, there are M(=22)×N (=22) divisions 301 in package substrate 300. Other values for M and N may be used in the present invention instead of a 22×22 matrix. Further, the values of M and N may not be the same. Divisions 301 of package substrate 300 may overlap different area portions of circuit substrate 400 (i.e. the semiconductor die) which may include functional circuitry formed in circuit substrate 400. According to some embodiments of the present invention such as depicted in FIG. 3, circuit substrate 400 may be a semiconductor die including functional circuitry, and package substrate 300 may include printed circuit board material. For example, the divisions in the shaded portion 320 of FIG. 3 may overlap various functional blocks formed in circuit substrate 400. Such functional blocks may include logic and memory circuits. Functional blocks may include memory arrays 420 and 430, coupled to SerDes circuits 401 and 402, and CRC circuit 410 of FIG. 4, which shows a layout of circuit substrate 400. While the embodiment depicted in FIG. 4 includes two memory arrays and two SerDes circuits, some embodiments of the present invention may use a different number of memory arrays and SerDes circuits. The divisions 301 in portion 321 (322) of package substrate 300 overlap first (second) SerDes circuit 401 (402). The divisions 301 in portion 310 of package substrate 300 overlap CRC circuit 410 (FIG. 4), according to the embodiment depicted in FIG. 3. Specifically, a given division 301 in package substrate 300 may overlap more than one functional component formed in circuit substrate 400. Also within shaded portion 320, divisions 344-1a (344-2a) and 344-1b (344-2b) may be coupled to conducting balls providing a signal or power to a sensitive circuit like a phase-locked loop (PLL) circuit in substrate 400. Serial interface 321 (322) may include portion 321a (322a) overlapping receiver unit 401a (402a) in SerDes 401 (402) of FIG. 4. Serial interface 321 (322) may also include portion 321b (322b) overlapping transmitter unit 401b (402b) in SerDes 401 (402) of FIG. 4.

Outside and along the edges of shaded portion 320 of package substrate 300, according to the embodiment depicted in FIG. 3, portions 315-1 to 315-16 and portions 316-1 to 316-16 may be provided. Portions 315-1 to 315-16 of the die substrate overlap divisions 301 of package substrate 300; divisions 301 may be coupled to Tx data channels 550-1 to 550-16 of package substrate 300 (see, FIG. 5c) through conducting balls 215, according to some embodiments of the present invention. Portions 316-1 to 316-16 of the die substrate also overlap divisions 301 of package substrate 300 coupled to Rx data channels 552-1 to 552-16 (see, FIG. 5c) through conducting balls 216.

Portion 375-1 (375-2) of the die substrate may be used to provide an extra Tx data channel 551-1 (551-2) (see, FIG. 5c) to integrated circuit 100. Likewise, portions 376-1 (376-2) overlap divisions 301 in package substrate 300 to potentially provide an extra Rx data channel 553-1 (553-2) (see, FIG. 5c) to integrated circuit 100.

FIG. 4 shows a layout of circuit substrate 400 for an integrated circuit which includes memory arrays 420 and 430, according to some embodiments of the present invention. In this embodiment, circuit substrate 400 includes a first SerDes circuit 401 and a second SerDes circuit 402, a CRC circuit 410, a first memory array 420, and a second memory array 430. Memory arrays 420 and 430 may include a number of memory cells 415. The number of memory arrays in circuit substrate 400 shown in FIG. 4 is merely exemplary. Some embodiments may include only one memory array, while some embodiments may include many memory arrays in circuit substrate 400 organized in various bank configurations. Some embodiments of the present invention may also include data lines 403 and 404 carrying data back and forth between two or more functional components 405 (see, FIG. 1). The data carried by lines 403 and 404 may be data packets in serial or parallel forms. For example, data line 403 may carry data packets in parallel form from SerDes 401 to CRC 410 and from there to memory cell 415. In turn, cell 415 may transmit data packets in parallel form to CRC circuit 410 and from there to SerDes 401, through data line 404. Furthermore, in some embodiments of the present invention data lines 403 and 404 may carry data packets in serial format through a portion of the data line, and parallel data packets through a different portion of the data line.

SerDes circuit 401 (402) may include receiver unit 401a (402a) and transmitter unit 401b (402b). Receiver unit 401a (402a) may receive data packets in serial format and convert them into parallel format before sending the data packets to CRC circuit 410 through data line 403. Transmitter unit 401b (402b) may convert data packets received in parallel form from CRC 410 into data packets in serial format and transmit the data out of circuit substrate 400 to external components.

Placing SerDes circuits 401 and 402 in a center portion of circuit substrate 400 according to the embodiment depicted in FIG. 4, with CRC circuit 410 in between SerDes circuits 401 and 402, decreases signal latency. This configuration provides a statistically balanced distance between SerDes circuits 401 and 402 and CRC circuit 410, and between SerDes circuits 401 and 402 and every memory cell 415 in circuit substrate 400. This configuration reduces worst-case delay through each memory array, thus providing an upper bound for signal latency. Accordingly, signal latency in circuit substrate 400 may be reliably predicted.

FIG. 5a is a conducting ball array map or bonding diagram, showing the positions of conductive balls 210 which couple package substrate 300 to underlying PCB 200, according to some embodiments of the present invention. For the area covered by portion 320 of FIG. 3, power and data may be coupled to bonding pads of circuit substrate 400 through conducting bumps 211 and 305 in package substrate 300. As seen in conjunction with FIG. 3, portion 320 overlaps conducting bumps 211 that provide power to enable functional components 405 in circuit substrate 400. Serial interface 321 (322) also includes portion 321a (322a) which overlaps conducting bumps 211 and conductive bumps 305 (FIG. 5b, described below) to provide power and data to receiver unit 401a (402a) within SerDes circuit 401 (402) in substrate 400. Serial interface 321 (322) also includes portion 321b (322b) which overlaps conducting bumps 211 and 305 that provide power to and data from transmitter unit 401b (402b) within SerDes circuit 401(402) in package integrated circuit 100.

Also shown in FIG. 5a are conducting balls 216-1a, 216-b to 216-16a, 216-16b coupled to Rx data channels carrying data packets from external components into receiver unit 401a (402a) in SerDes circuit 401 (402). According to the embodiment depicted in FIG. 5a, balls 216-1a, 216-1b to 216-8a, 216-8b may be associated with bits ‘0’ to ‘7’ in an 8-bit receiving unit 401a. Likewise, balls 216-9a, 216-9b to 216-16a, 216-16b may be associated with bits ‘8’ to ‘15’ in an 8-bit receiving unit 402a. According to some embodiments of the present invention, each data bit is associated with two different conducting balls, labeled ‘a’ and ‘b’, respectively, with the data bit being represented by a differential signal. Thus, balls 216-1a and 216-1b may couple the first data bit (‘0’) in an 8-bit data word, and balls 216-8a and 216-8b may couple the last data bit (‘7’) of the 8-bit data word being received by unit 401a. Likewise, conducting balls 216-9a and 216-9b may couple the first data bit (‘8’) in an 8-bit data word, and conducting balls 216-16a and 216-16b may couple the last data bit (‘15’) of the data word being received by receiver unit 402a.

In the embodiment depicted in FIG. 5a, first SerDes circuit 401 (covered by 321) and second SerDes circuit 402 (covered by 322) handle the serial data link in packaged integrated circuit 100. Each of the SerDes circuits 401 and 402 receives an 8-bit data word that may be part of a larger frame being transferred through the serial data link. For example, a data frame may have an 80-bit data packet that can be processed by each of SerDes circuits 401 and 402.

FIG. 5a shows conducting balls 516-1a, 516-1b, and 516-2a, 516-2b. Conducting balls 516-1a, 516-1b (516-2a, 516-2b) may carry two differential signals coupled to an extra data bit (e.g., a parity bit) to accompany the 8-bit word being received by receiver unit 401a (402a).

Conducting balls 215-1a, 215-1b to 215-16a, 215-16b are coupled to Tx data channels carrying data packets from functional components 405 to transmitter unit 401b (402b) in SerDes circuit 401 (402). According to the embodiment depicted in FIG. 5a, balls 215-1a, 215-1b to 215-8a, 215-8b may be associated with bits ‘0’ to ‘7’ in an 8-bit transmitting unit 401b. Likewise, balls 215-9a, 215-9b to 215-16a, 215-16b may be associated with bits ‘8’ to ‘15’ in an 8-bit transmitter unit 402b. According to some embodiments of the present invention, each data bit is associated with two different conducting balls as the data bit is being represented by a differential signal. Thus, conducting balls 215-1a, 215-1b may couple the first data bit (‘0’) in an 8-bit data word, and conducting balls 215-8a, 215-8b may couple the last data bit (‘7’) of the data word being transmitted by transmitter unit 401b. Conducting balls 215-9a, 215-9b may couple the first data bit (‘8’) in an 8-bit data word while conducting balls 215-16a, 215-16b may couple the last data bit (‘15’) of the data word being transmitted by unit 402b.

Further shown in FIG. 5a are conducting balls 515-1a, 515-1b, and 515-2a, 515-2b. Conducting balls 515-1a, 515-1b (515-2a, 515-2b) may carry two differential signals coupled to an extra data bit (e.g., parity bit) that may be added to the 8-bit word being transmitted (515-1a, 515-1b and 515-2a, 515-2b) by transmitter unit 401b (402b).

According to some embodiments of the present invention, as depicted in FIG. 5a, conducting bumps 211 may include conducting bumps 211-1a and 211-1b. Conducting bumps 211-1a and 211-1b may carry differential signals coupled to a clock signal being received by packaged integrated circuit 100. The clock signal may be used by functional components 405 in circuit substrate 400, including SerDes circuits 401 and 402, and CRC circuit 410.

FIG. 5b is a conducting bump array map or bonding diagram which shows the positions of conducting bumps 211 and 305 which couple package substrate 300 to circuit substrate 400, according to some embodiments of the present invention. Elements 211-2, indicated in FIG. 5b by circles filled in black, are conducting bumps providing a reference voltage Vₛₛ (e,g, the ground voltage) to functional components 405 in circuit substrate 400. Elements 211-3, indicated in FIG. 5b by circles filled with slanted hashing, are conducting bumps providing a voltage V_{dd} to functional components 405 in circuit substrate 400 (see FIG. 1). According to some embodiments of the present invention, the value of voltage V_{dd} may be 1.0 V. Some embodiments of the present invention may use other values of V_{dd}, such as 1.5 V or an even higher voltage. Functional components 405 coupled to conducting bumps 211-2 and 211-3 may be memory cells 415 or logic circuits, such as found in CRC circuit 410, according to some embodiments of the present invention. Elements 211-4, indicated in FIG. 5b by circles filled with dots, are conducting bumps coupled to a power supply providing a voltage V_{ddhvmem} to memory cells 415 to generate bit line voltages, according to some embodiments of the present invention. In some embodiments, the value of V_{ddhvmem} may be 1.5 V; other embodiments may have higher values of V_{ddhvmem} such as 1.7 V, 2.0 V or even higher. Elements 211-5, indicated in FIG. 5b by circles filled with cross-hatching, are conducting bumps coupled to a power supply providing a voltage V_{dd}_{_{—}}_{sds} to functional components 405 in circuit substrate 400. In accordance with the present invention, conducting bumps 211-5 may provide power to SerDes circuits 401 and 402 in circuit substrate 400. In some embodiments of the present invention, voltage V_{dd}_{_{—}}_{sds} may be 1.0 V; while other embodiments may use a higher value for V_{dd}_{_{—}}_{sds} (e.g., 1.1 V or 1.5 V). Elements 211-6, indicated in FIG. 5b by circles filled with white background, are conducting bumps that may provide a power supply having a voltage V_{ddhv}_{_{—}}_{sds} to functional elements 405 in circuit substrate 400. In some embodiments of the present invention, functional elements 405 enabled by V_{ddhv}_{_{—}}_{sds} may be active components of SerDes circuits 401 and 402, such as a phase locked-loop (PLL) unit including a voltage controlled oscillator (VCO). In some embodiments of the present invention, voltage V_{ddhv}_{_{—}}_{sds} may have a value of 1.5 V or higher; some embodiments may use a value of V_{ddhv}_{_{—}}_{sds} approximately equal to 1.7 V, or 2.0 V, or even higher, such as 3.3 V or 5.0 V.

Also shown in FIG. 5b are conducting bumps 305-1 and 305-2. Bumps 305-1 couple the data channels in package substrate 300 to functional components 405 in circuit substrate 400. Conducting bumps 305-1 may couple data channels related to bits ‘0’ through ‘7’ in portion 321 and bits ‘8’ to ‘15’ in serial interface 322. Conducting bumps 305-2 may couple data channels related to extra data bits that may be included in the data packet being received in units 401a and 402a, or transmitted in units 401b and 402b. Some data channels may be coupled to data access channels in PCB layer 200 through lines in package substrate 300 to conducting balls 216-1a, 216-1b to 216-15a, 216-15b for receiver units 401a and 402a, within portions 321a and 322a. Similarly, some data channels may be coupled to data access channels in PCB layer 200 through lines in package substrate 300 to conducting balls 215-1a, 215-1b to 215-15a, 215-15b for transmitter units 401b and 402b, within portions 321b and 322b.

FIG. 5c is a layout of package substrate 300 showing the positions of conducting balls 215-1a, 215-1b to 215-15a, 215-15b, 216-1a, 216-1b to 216-15a, 216-15b, coupled to package substrate 300. Also shown are conducting balls 515-1a, 515-1b, 515-2a, 515-2b, 516-1a, and 516-1b, and 516-2a, 516-2b coupled to package substrate 300. Also shown in FIG. 5c are Rx data lines 552-1 to 552-16, 553-1 and 553-2, and Tx data lines 550-1 to 550-16, 551-1 and 551-2 in package substrate 300, according to some embodiments of the present invention. By using Tx/Rx data lines in package substrate 300 as depicted in FIG. 5c, the latency of a memory array for a data line in a package substrate having a length of approximately 8-10 mm according to the embodiment depicted in FIG. 5c may be less than 100 picoseconds (ps), and more preferably, the latency is less than 70 ps or less within the package substrate. By comparison, the latency for a Tx/Rx data line in circuit substrate 400 that may be found in the prior art carrying data signals from one edge of a die to the opposite edge of the die within a silicon substrate may have a latency ten times greater, or about 2-4 ns (nanoseconds), or even more.

Conducting balls 216-1a,b to 216-16a,b are coupled to Rx data lines 552-1 to 552-16; conducting balls 516-1a,b are coupled to Rx data line 553-1; and conducting balls 516-2a, 516-2b are coupled to Rx data line 553-2. Conducting balls 215-1a, 215-1b to 215-16a, 215-16b are coupled to Tx data lines 550-1 to 550-16; conducting balls 515-1a, 515-1b are coupled to Tx data line 551-1; and conducting balls 515-2a, 515-2b are coupled to Tx data line 551-2. All other elements in FIG. 5c are as described in detail in FIGS. 1-5b above.

According to some embodiments of the present invention, Rx data lines 552-1 to 552-16, 553-1, 553-2, and Tx data lines 550-1 to 550-16, 551-1, 551-2 may carry their respective signals as differential signals.

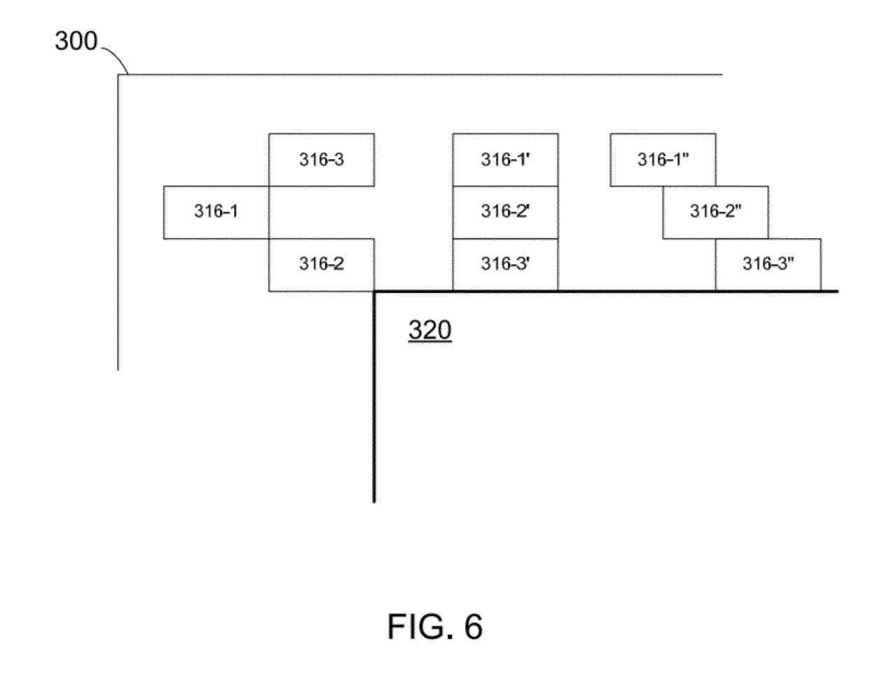

FIG. 6 shows three different arrangements for placing Rx signal pairs in package substrate 300, using portions 316-1 to 316-3 (see, e.g., FIG. 3). Portions 316-1 to 316-3 each overlap a complementary signal pair (i.e., a differential signal); the signal pairs are staggered. This configuration corresponds to that shown in FIG. 3 and FIG. 5c. Some embodiments of the present invention may use a configuration illustrated by portions 316-1′ to 316-3′ of FIG. 6. In portions 316-1′ to 316-3′ the signal pairs are “vertically” aligned on package substrate 300 (i.e., parallel to an edge of circuit substrate 400). Other embodiments may use a “chevron” pattern, as illustrated by portions 316-1″ to 316-3″. Note that area portions 316-1 to 316-3, 316-1′ to 316-3′, and 316-1″ to 316-3″ lay outside portion 320. Portion 320 overlaps conducting bumps 211 that provide power to enable functional components 405 in circuit substrate 400 (see, FIGS. 3 and 4). For each of the three Rx signal pair configurations shown in FIG. 6 a corresponding Tx signal pair configuration may be created having the same configuration and located on the opposite side of packaged substrate 300. That is, for Rx signal pairs having a staggered configuration, Tx signal pairs may also have a staggered configuration; for Rx signal pairs having a vertical configuration, Tx pairs may also have a vertical configuration; and for Rx pairs having a chevron configuration, Tx pairs may also have a chevron configuration. Other embodiments may have different arrangements, with the Rx signal pairs and the Tx signal pairs having similar shapes. While Rx and Tx signal lines are located on opposite sides of package substrate 300, they may use signal paths having similar lengths and shapes. Thus, an Rx signal line from portion 316-1a, 315-1b to conducting bump 305 in portion 321a may have the same path length as a Tx signal line from portion 315-1a, 315-1b to a conducting bump 305 in portion 321b. Furthermore, the present invention may alternate an Rx signal pair with a Tx signal pair, to produce any one of the patterns depicted in FIG. 6.

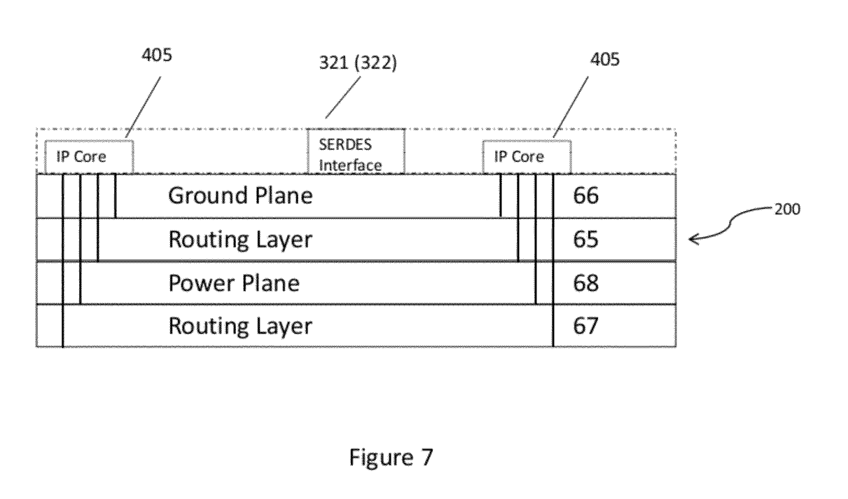

FIG. 7 illustrates a cross section of a package containing a multi-layer PCB and suitable functional blocks 405. SERDES interface 321 (322) lies on the central axis (FIG. 5C), and is flanked by IP cores 405. Unlike the present invention, conventional packages contain anywhere from eight or more layers. In the present invention, the substrate of IC device 100 may contain fewer layers than the prior art, and even as few as four layers since the signals over the Rx data lines are less likely to interfere with signals being transmitted over a Tx data line. In FIG. 7, PCB 200 includes a ground plane 66, power plane 68 and two routing layers 65, 67. Vias 75 couple the terminals on the upper surface of the package to routing layers 65 and 67.

The ability to have separated Rx and Tx signal lines allows the placing of all signal lines on the same layer in package substrate 300. This arrangement reduces the number of layers that may be used in package substrate 300. Further, by placing Rx and Tx signal pairs in configurations such as 316-1 to 316-3, 316-1′ to 316-3′, and a chevron pattern as in 316-1″ to 316-3″, a time differential may be introduced between the data channels. That is, the timing of the signal pulses in channel 316-1 may be slightly different from the timing of the signal pulses in channels 316-2 and 316-3. Thus, electromagnetic interference between the signal channels 316-1, 316-2 and 316-3 may be suppressed. The same situation may be found for a configuration as in channels 316-1′ to 316-3′, and in a configuration as in channels 316-1″ to 316-3″.

This disclosure enables those of ordinary skill in the art to appreciate still additional variations in design of a packaged integrated circuit with serial data links. Thus, while specific embodiments and applications of the present invention have been illustrated and described, the invention is not limited to the exemplary embodiments disclosed herein. For instance, the voltages described above are representative only; other voltages may be used depending on the specific design application. In addition, it is not essential to include the same number of Rx signal pairs as the number of Tx signal pairs in an IC to achieve the advantages of the present invention. Accordingly, various modifications may be made to the arrangement, operation and details of the present invention without departing from the scope of the invention. The scope of the invention will be limited only according to the following claims.

1. A packaged integrated circuit to be coupled to a printed circuit board (PCB) providing power lines and data access channels, comprising:
a package substrate having transmit data channels, receive data channels and power lines formed thereon, wherein the transmit data channels and the receive data channels are located on opposite sides of the package substrate;
a circuit substrate having functional components formed therein, wherein
(i) the power lines and the data channels on the package substrate are coupled to the functional components of the circuit substrate by conducting bumps;
(ii) the power lines and the data access channels on the PCB are coupled to the data channels and power lines of the package substrate through conducting balls; and wherein
(iii) the conducting balls coupling the data access channels of the PCB and the data channels in the package substrate are located along the edges of the package substrate; and
(iv) the conducting balls coupling the power lines in the PCB and the power lines in the package substrate are located in an interior portion of the package substrate.

2. The packaged integrated circuit as in claim 1 wherein the circuit substrate is a semiconductor die.

3. The packaged integrated circuit as in claim 1, further comprising data lines formed on the package substrate that each carry data between a conducting bump and a conducting ball.

4. The packaged integrated circuit as in claim 1 wherein the circuit substrate comprises data lines carrying data between the conducting bumps and the functional components.

5. The packaged integrated circuit as in claim 1, wherein the data channels comprise transmit data channels, receive data channels, and clock lines.

6. The packaged integrated circuit as in claim 5, wherein each of the transmit and receive data lines comprises a pair of data channels.

7. The packaged integrated circuit as in claim 1, wherein the pair of data channels in each of the transmit and receive data lines is arranged in a differential signal configuration.

8. The packaged integrated circuit as in claim 1, wherein each transmit data channel corresponds to a receive data channel in the package substrate.

9. The packaged integrated circuit as in claim 1, wherein the transmit data channels and the receive data channels do not cross over each other within any of the metal layers of the semiconductor die.

10. The packaged integrated circuit as in claim 1, wherein the transmit data channels are nonparallel over their entire length to the receive data channels.

11. The packaged integrated circuit as in claim 1, wherein:
the transmit and receive data channels in the package substrate comprise serial data channels; and the functional components in the circuit substrate comprise at least one of a serializer-deserializer (SerDes) circuit; an error detection circuit; an array of memory cells or an array of computational elements.

12. An integrated circuit to be placed on a printed circuit board (PCB) providing power lines and data access channels; comprising:
a circuit substrate having formed thereon active components including a SerDes circuit located at a center portion of the circuit substrate;
a package substrate having formed thereon transmit and receive data channels, and power lines; wherein:
the data channels in the package substrate are coupled to the active components of the circuit substrate by conducting bumps;
the power lines and the data access channels in the PCB are respectively coupled to the power lines and the transmit and receive data channels in the package substrate through conducting balls;
the conducting balls coupling the data access channels in the PCB to the transmit and receive data channels in the package substrate are located along the edges of the package substrate;
the conducting balls coupling the power lines in the PCB and the power lines in the package substrate are located in an interior portion of the package substrate.

13. A method of forming a packaged memory circuit to be coupled to a printed circuit board (PCB) layer providing power lines and data access channels, the packaged memory comprising:
a package substrate having data channels and power lines formed thereon;
a circuit substrate having functional components formed therein, the method comprising the steps of:
(i) forming power lines and the data channels on the package substrate coupled to the functional components of the circuit substrate by conducting bumps;
(ii) forming power lines and the data access channels on the PCB coupled to the data channels and power lines of the package substrate through conducting balls;
(iii) forming conducting balls coupling the data access channels of the PCB and the data channels in the package substrate along the edges of the package substrate; and
(iv) forming conducting balls coupling the power lines in the PCB and the power lines in the package substrate in an interior portion of the package substrate.

14. The method as in claim 13, further wherein:
the data channels in the package substrate comprise transmit and receive serial data channels; and
the functional components in the circuit substrate comprise a serializer-deserializer (SerDes) circuit; an error detection circuit; and an array of computational elements.
